(19) United States
(12) Patent Application Publication
(10) Pub. No.: US 2019/0387625 A1
(43) Pub. Date: Dec. 19, 2019

(54) ELECTRIC PRODUCT

(71) Applicant: KAWASAKI JUKOGYO KABUSHIKI KAISHA, Kobe-shi, Hyogo (JP)

(72) Inventor: Tsuyoshi TAGASHIRA, Kakogawa-shi (JP)

(73) Assignee: KAWASAKI JUKOGYO KABUSHIKI KAISHA, Kobe-shi, Hyogo (JP)

(21) Appl. No.: 16/464,311

(22) PCT Filed: Nov. 24, 2017
(86) PCT No.: PCT/JP2017/042163

§ 371 Date: May 28, 2019

(30) Foreign Application Priority Data
Nov. 25, 2016 (JP) 2016-228898

(51) Int. Cl. H05K 1/14; H05K 3/36; H05K 7/14

(52) U.S. Cl. CPC H05K 1/14; H05K 7/14; H05K 3/36

(57) ABSTRACT

An electric product includes a substrate laminate configured by laminating a plurality of electronic circuit substrates with an electronic component on at least one of a front surface and a back surface, wherein the plurality of electronic circuit substrates include one electronic circuit substrate and the other electronic circuit substrate of the two electronic circuit substrates adjacent to each other, and wherein the substrate laminate has a positioning unit for positioning the one electronic circuit substrate and the other electronic circuit substrate to each other when laminating the one electronic circuit substrate and the other electronic circuit substrate to each other. An electric product with a laminate in which a plurality of electronic circuit substrates are laminated can be easily and efficiently manufactured using a robot.

### TECHNICAL FIELD

The present invention relates to an electric product provided with a substrate laminate in which a plurality of electronic circuit substrates on which electronic components are implemented are laminated.

### BACKGROUND ART

In recent years, integration and miniaturization of electronic circuits have progressed, and particularly in printed substrates, a large number of printed substrates on which a large number of electronic components including integrated circuits are implemented are used in electric products, such as control devices. Moreover, in order to use space effectively, the substrate laminate on which a plurality of printed substrates on which a large number of electronic components are implemented is mounted.

Moreover, in the printed substrate, automation is progressing with advances in printing technology and the like. In addition, implementation of electronic components on printed substrates is also increasingly automated.

However, in the case of substrate laminates in particular, conventionally, wiring between substrates or the like has been routed around the inside of the casing of an electric product (such as a control device) using a harness (wire harness or cable harness) in which a large number of electric wires are bundled so as to perform connection between connectors (terminals). For this reason, the miniaturization of the casing is restricted, and connector connection is difficult to automate and has been performed manually. Therefore, there existed a problem that a lot of labor and time were required for manufacturing an electric product.

For such a problem of the conventional art, for example, Patent Document 1 proposes that two printed substrates are connected by a robot. That is, Patent Document 1 proposes a method that an implement substrate 6 is held by a substrate handling robot 18 and pressed onto a battery substrate 5, and a connector 10a of the battery substrate 5 and a connector 10b of the implement substrate 6 are engaged with each other to connect the substrates 5 and 6 (for example, paragraph [0012]).

Here, in order to engage the connector 10a with the connector 10b of the implement substrate 6 by the robot 18, it is necessary to accurately position the battery substrate 5 which is the engaging partner. Therefore, in order to securely connect the connectors 10a and 10b, a substrate positioning device 15 independent of the robot 18 is prepared, and the battery substrate 5 is accurately positioned by the substrate positioning device 15 before the connection of the connectors 10a and 10b by the robot (for example, the latter part of paragraph [0011] to the first part of [0012]).

Therefore, in the method according to Patent Document 1, a new dedicated positioning device is required to securely connect the connectors 10a and 10b, and the number of steps for positioning also increases, thereby increasing costs, labor and time. Further, the method according to Patent Document 1 is only intended to connect two substrates, not to connect three or more multiple substrate laminates.

As described above, conventionally, there has been a problem that it is difficult to easily and efficiently manufacture an electric product, for example, a control device provided with a laminate in which a plurality of electronic circuit substrates are laminated using a robot.

### CITATION LIST

Patent Document

[Patent Document 1] Japanese Patent Application Laid-open No. H04-280497

### SUMMARY OF INVENTION

### Objects to be Achieved by the Invention

The present invention is made considering the above-described problems of the conventional technology, and its object is to provide an electric product provided with a laminate in which a plurality of electronic circuit substrates are laminated, which can be easily and efficiently manufactured using a robot.

### Means for Achieving the Objects

In order to achieve the above-mentioned objects, a first aspect of the present invention is an electric product comprising a substrate laminate configured by laminating a plurality of electronic circuit substrates provided with an electronic component on at least one of a front surface and a back surface, wherein the plurality of electronic circuit substrates include one electronic circuit substrate and the other electronic circuit substrate of the two electronic circuit substrates adjacent to each other, and wherein the substrate laminate has a positioning unit for positioning the one electronic circuit substrate and the other electronic circuit substrate to each other when laminating the one electronic circuit substrate and the other electronic circuit substrate to each other.

A second aspect of the present invention is that, in the first aspect, the one electronic circuit substrate has a positioning pin provided with its tip end directed to the other electronic circuit substrate, and one connector terminal of an electric connector, and wherein the other electronic circuit substrate has a fitting hole in which the positioning pin is fitted, and the other connector terminal provided with its tip end directed to the one electronic circuit substrate and connected to the one connector terminal.

A third aspect of the present invention is that, in the first aspect, the one electronic circuit substrate has one connector terminal of an electric connector, wherein the other electronic circuit substrate has the other connector terminal connected to the one connector terminal, and wherein the one connector terminal and the other connector terminal have a function of positioning the one electronic circuit substrate and the other electronic circuit substrate to each other when laminating the one electronic circuit substrate and the other electronic circuit substrate to each other.

A fourth aspect of the present invention is that, in the second or third aspect, an electronic circuit substrate having the other connector terminal on the back surface has a gripping portion which is gripped by a robot when assembling or disassembling the substrate laminate on a portion of the front surface corresponding to the other connector terminal.

A fifth aspect of the present invention is that, in any one of the second to fourth aspects, the one connector terminal and the other connector terminal are a male terminal and a female terminal, or a plug and a receptacle.

A sixth aspect of the present invention comprises, in any one of the first to fifth aspects, an attachment portion to which an electronic circuit substrate of the lowermost layer of the substrate laminate is attached, wherein the attachment portion has a positioning pin provided with its tip end directed to the electronic circuit substrate of the lowermost layer, and wherein the electronic circuit substrate of the lowermost layer has a fitting hole in which the positioning pin of the attachment portion fits.

A seventh aspect of the present invention is that, in the sixth aspect, the attachment portion is integrally formed with a container for storing the substrate laminate.

### BRIEF DESCRIPTION OF THE DRAWINGS

FIG. 1 is an exploded perspective view from diagonally above a substrate laminate (four layers) in one embodiment of an electric product according to the present invention.

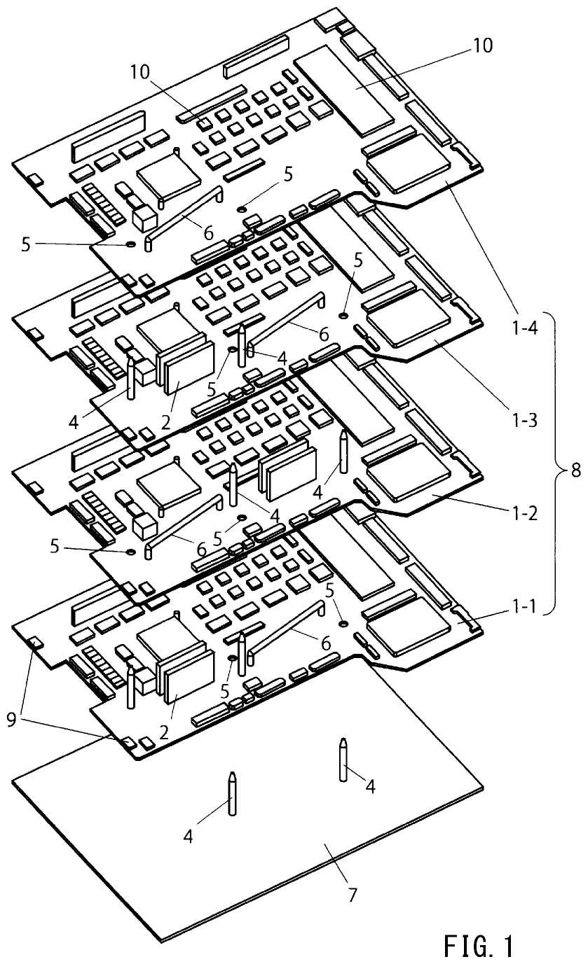

FIG. 2 is an exploded perspective view from diagonally below the substrate laminate (four layers) in one embodiment of the electric product according to the present invention.

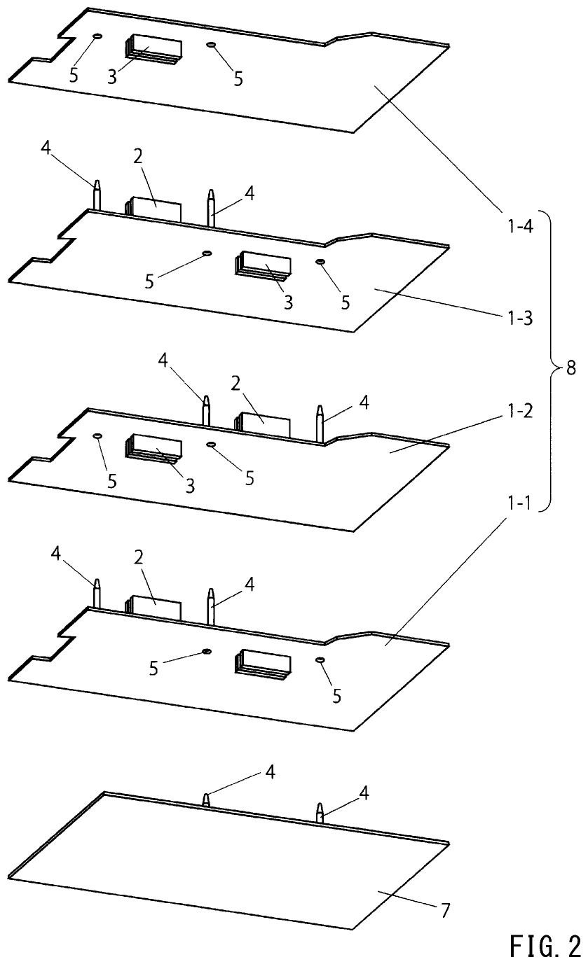

FIG. 3 is an exploded perspective view from diagonally above a second layer and a third layer of the substrate laminate (four layers) in one embodiment of the electric product according to the present invention.

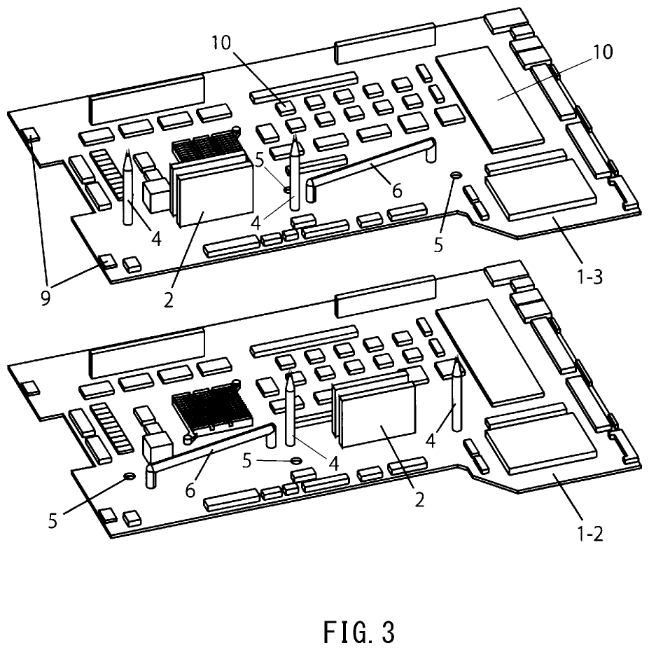

FIG. 4 is an exploded perspective view from diagonally below the second layer and the third layer of the substrate laminate (four layers) in one embodiment of the electric product according to the present invention.

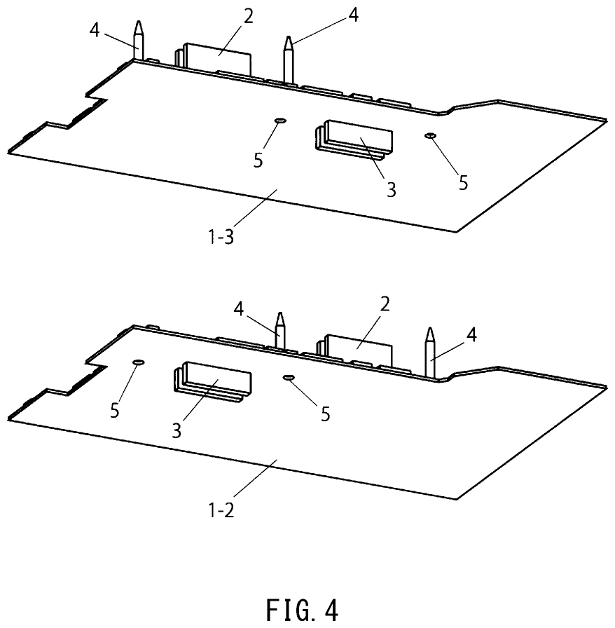

### EMBODIMENT OF THE INVENTION

Hereunder, one embodiment of the electric product according to the present invention will be described referring to the drawings.

The electric product according to this embodiment comprises a substrate laminate 8 in which four (four layers of) electronic circuit substrates (hereunder, sometimes simply referred to as “substrate”) 1-i (i=1, 2, 3, 4) installing electronic component 10 on the surface are laminated, a placing table (attachment portion) 7 to which the back surface of the substrate 1-1 of the lowermost layer (first layer) is attached, and a casing (not illustrated) for storing the substrate laminate 8 and the placing table 7 inside.

Note that, in regards to the substrate 1-i, the lowermost layer attached to the placing table 7 is the first layer 1-1 (i=1), and the rest are referred to as the second layer 1-2 (i=2), the third layer 1-3 (i=3), and the fourth layer 1-4 (i=4) in order towards the top. In addition, the substrate 1-i may be collectively referred to simply as a substrate 1. Further, in each substrate 1-i, the surface on the lower side (the side of the placing table 7) is the back surface, and the surface on the upper side (the opposite side to the placing table 7) is the front surface. Further, in the embodiment described below, the electronic component 10 is implemented on the front surface of the substrate 1, while it may be implemented on the back surface or both front and back surfaces.

The placing table 7 is preferably formed integrally with the casing. This is because, when the substrate 1 is provided with an electronic component having a large amount of heat generation such as a power semiconductor, high heat dissipation performance can be ensured.

First, the structure of the substrates 1-2 and 1-3 which are the intermediate layers (in this embodiment, the second and third layers excluding the first layer which is the lowermost layer and the fourth layer which is the uppermost layer) of the substrate laminate 8 will be described focusing on the substrate 1-3.

In a portion wherein the electronic component 10 is not installed on the surface of the substrate 1-2 of the second layer, a connector terminal (female or receptacle) 2 for connecting to a connector terminal (male or plug) 3 for electrical wiring disposed on the substrate 1-3 of the third layer is disposed with its tip end directed to (the back surface of) the substrate 1-3 of the third layer, and on both sides of the connector terminal 2, a pair of positioning pins (positioning unit) 4 whose tip ends are directed to the back surface of the substrate 1-3 of the third layer are disposed, and further, a bar 6 which is a gripping portion gripped by the robot hand in order to connect or separate the substrate 1-2 of the second layer with the substrate 1-1 of the first layer is disposed.

Additionally, on the back surface of the substrate 1-2 of the second layer, the connector terminal (male or plug) 3 for connecting with the connector terminal (female or receptacle) 2 for electrical wiring is disposed at the corresponding position of the bar 6 with the tip end directed to the surface of the substrate 1-1 of the first layer.

Further, in the substrate 1-2 of the second layer, a fitting hole (positioning unit) 5 is disposed in which the positioning pin 4 disposed on the surface of the substrate 1-1 of the first layer is fitted with the tip end directed to the substrate 1-2 of the second layer.

Similarly, in a portion wherein the electronic component 10 is not installed on the surface of the substrate 1-3 of the third layer, the connector terminal (female or receptacle) 2 for connecting to the connector terminal (male or plug) 3 for electrical wiring disposed on the substrate 1-4 of the fourth layer is disposed with its tip end directed to the back surface of the substrate 1-4 of the fourth layer, and on both sides of the connector terminal 2, a pair of positioning pins 4 whose tip ends are directed to the back surface of the substrate 1-4 of the fourth layer are disposed, and further, the bar 6 which is a gripping portion gripped by the robot hand in order to connect or separate the substrate 1-3 of the third layer with the substrate 1-2 of the second layer is disposed.

Additionally, on the back surface of the substrate 1-3 of the third layer, the connector terminal (male or plug) 3 for connecting with the connector terminal (female or receptacle) 2 for electrical wiring is disposed at the corresponding position of the bar 6 with the tip end directed to the surface of the substrate 1-2 of the second layer. Further, in the substrate 1-3 of the third layer, the fitting hole 5 is disposed in which the positioning pin 4 disposed on the surface of the substrate 1-1 of the second layer is fitted with the tip end directed to the substrate 1-3 of the third layer.

The positioning pin 4 disposed on the substrates 1-1, 1-2 and 1-3 has a tip end formed in a substantially conical shape, and the main body portion is formed of a rod-like member having a circular cross section so that positioning can be performed when joining the connector terminal 2 and the connector terminal 3 by a robot. The effective length of the circular cross section is set to be longer than the distance between adjacent substrates 1-i.

Further, the substrate 1-i is marked with a silk printing or the like at a predetermined marking portion 9 so that the robot can grip the predetermined gripping portion of the substrate 1-i with a predetermined accuracy.

Next, a method of assembling the substrate 1-3 in a state wherein the substrates 1-1 and 1-2 are assembled with respect to the substrate laminate 8 having the above-described structure will be described.

The position of the marking position of the substrate 1-3 carried into the work area is measured by a vision device using a TV camera or the like, the position and orientation of the substrate 1-3 are detected, and after the robot grips a predetermined gripping portion to transfer the substrate 1-3 to a position vertically above the substrate 1-2, the positioning pin 4 of the substrate 1-2 is lowered so that it fits into the fitting hole 5 of the substrate 1-3 so that the connector terminal 3 of the substrate 1-3 is connected to the connector terminal 2 of the substrate 1-2. Note that, mechanical copying mechanism such as a compliance mechanism may be provided or software copying control may be added to the robot hand so that the inner surface of the fitting hole 5 of the substrate 1-3 can be positioned in a horizontal surface copying the substantially conical shape of the tip end of the positioning pin 4 of the substrate 1-2.

In order to secure the connection of the connector terminal 3 of the substrate 1-3 to the connector terminal 2 of the substrate 1-2, the bar 6 is pressed downward by an appropriate pressing force by the robot hand, as necessary.

Conversely, when separating the substrate 1-3 from the substrate 1-2, the bar 6 is gripped by a robot or a hand to separate the connector terminal 3 of the substrate 1-3 from the connector terminal of the substrate 1-2.

Since the connector terminals 2 and 3 often have several dozens to 100 or more of multipoles/multicores, they often require considerable force for their attachment and detachment. While, since the substrate 1 is made of a synthetic resin or the like and may not have sufficient strength, the substrate 1 may be damaged when the connector terminal 2 and the connector terminal 3 are attached and detached by gripping the end portion of the substrate 1 or the like.

Therefore, in this embodiment, by gripping and operating (pressing or pulling away) the bar 6 disposed at the position of the surface corresponding to the connector terminal 2 disposed on the back surface, the substrate 1 is prevented from being damaged or the like when the connector terminal 2 and the connector terminal 3 are attached and detached.

Next, the structures of the substrate 1-1 of the first layer which is the substrate 1 of the lowermost layer of the substrate laminate 8 and the substrate 1-4 of the fourth layer which is the substrate 1 of the uppermost layer will be described.

The connector terminal 3 is not disposed on the substrate 1-1 of the first layer, since there is no substrate 1 to be connected to the lower side of the substrate 1-1.

Further, since the connector 3 is not disposed on the substrate 1-1, when the substrate 1-1 is separated from the placing table 7, the fitting hole of the substrate 1-1 is simply pulled out from the positioning pin 4 of the placing table 7. Therefore, it does not require a large force and there is a low risk of damaging or the like the substrate 1-1 even if the end portion of the substrate 1-1 is gripped and operated, and therefore it does not need to dispose the bar 6 necessarily.

Further, the connector terminal 2 and the positioning pin 4 are not disposed on the substrate 1-4 of the fourth layer which is the substrate 1 of the uppermost layer, since there is no substrate 1 to be connected to the upper side of the substrate 1-4.

Note that, in this embodiment, the connector terminal (female or receptacle) 2 is disposed on the substrate 1 of the lower layer (for example, substrate 1-2) and the connector terminal (male or plug) 3 is disposed on the substrate 1 of the upper layer (for example, substrate 1-3) between the substrates 1 of the upper and lower layers adjacent to each other (for example, substrates 1-2 and 1-3). Conversely, however, the connector terminal (male or plug) 3 may be disposed on the substrate 1 of the lower layer (for example, substrate 1-2) and the connector terminal (female or receptacle) 2 may be disposed on the substrate 1 of the upper layer (for example, substrate 1-3). Further, as long as the connector terminal (male or plug) 3 and the connector terminal (female or receptacle) 2 are connected, either may be disposed on the substrate of the upper layer or the lower layer.

Note that, although the substrate laminate of four layers is described in this embodiment, the present invention should just have a laminate of two or more layers.

In the case of a substrate laminate having two layers, in the substrate laminate having the four layers in this embodiment, it has only the lowermost layer (first layer) and the uppermost layer (fourth layer) excluding the intermediate layers (second and third layers), and in the case of a laminate having three or more layers, the intermediate layer having the same structure is added.

In this embodiment, the connector terminal (male or plug) 3 and the connector terminal (female or receptacle) 2 having an appropriate structure are combined. Thereby, for a small positional deviation between the connector terminal 3 and the connector terminal 2, both can be effectively connected following the shape of the tip end by pushing one of the connector terminal 3 and the connector terminal 2 into the other.

Accordingly, in the substrate laminate 8 according to this embodiment, even when there is an error or the like in the positioning of the electric product or placing table 7 which is the other party of the assembly, and the robot hand cannot grip the substrate 1 with the correct position or posture, the positioning pin can position the connector terminal 3 and the connector terminal 2 within the connectable range for a predetermined large displacement, and the connector terminal 3 and the connector terminal 2 can be connected as a displacement within the allowable connection range of the original connector terminal 3 and the connector terminal 2 for a small displacement.

Further, since the electrical wiring is connected between the adjacent substrates 1 by the connector terminal 2 and the connector terminal 3, wiring of the harness in the casing and connection of the harness connector become unnecessary. Therefore, it becomes possible to miniaturize the casing and to automatically assemble the substrate laminate by a robot, thereby achieving cost reduction and rationalization of production.

Further, the substrate laminate 8 according to this embodiment does not damage the substrate 1 since the connector terminal 3 and the connector terminal 2 are attached and detached by gripping the bar 6.

In the embodiment described above, positioning unit for positioning one electronic circuit substrate and the other electronic circuit substrate when laminating the one electronic circuit substrate and the other electronic circuit substrate to each other is configured by the positioning pin 4 and the fitting hole 5.

As another embodiment of the present invention, instead of the positioning unit configured by the positioning pin 4 and the fitting hole 5 described above, when laminating one electronic circuit substrate and the other electronic circuit substrate, one connector terminal and the other connector terminal may be configured to have a function of positioning one electronic circuit substrate and the other electronic circuit substrate to each other.

Since the positioning unit is constituted by one connector terminal and the other connector terminal in this embodiment, the configuration can be simplified.

### DESCRIPTION OF REFERENCE NUMERALS

1 . . . electronic circuit substrate
1-1 . . . electronic circuit substrate (first layer)
1-2 . . . electronic circuit substrate (second layer)
1-3 . . . electronic circuit substrate (third layer)
1-4 . . . electronic circuit substrate (fourth layer)
2 . . . connector terminal (female or receptacle)
3 . . . connector terminal (male or plug)
4 . . . positioning pin (positioning unit)
5 . . . fitting hole (positioning unit)
6 . . . bar
7 . . . placing table (mounting unit)
8 . . . substrate laminate
9 . . . marking unit
10 . . . electronic component

1. An electric product comprising:
a substrate laminate configured by laminating a plurality of electronic circuit substrates, each of which has an electronic component mounted on at least one of a front surface and a back surface thereof,
wherein the plurality of electronic circuit substrates include one electronic circuit substrate and an other electronic circuit substrate of two electronic circuit substrates which are adjacent to each other, and
wherein the substrate laminate has a positioning unit configured to position the one electronic circuit substrate and the other electronic circuit substrate to each other when laminating the one electronic circuit substrate and the other electronic circuit substrate to each other.

2. The electric product according to claim 1,
wherein the one electronic circuit substrate is provided with a positioning pin having a tip end which is directed to the other electronic circuit substrate, and one connector terminal of an electric connector, and
wherein the other electronic circuit substrate is provided with a fitting hole in which the positioning pin is fitted, and an other connector terminal having a tip end, which is directed to the one electronic circuit substrate, and connected to the one connector terminal.

3. The electric product according to claim 1,
wherein the one electronic circuit substrate has one connector terminal of an electric connector,
wherein the other electronic circuit substrate has an other connector terminal connected to the one connector terminal, and
wherein the one connector terminal and the other connector terminal have a function of positioning the one electronic circuit substrate and the other electronic circuit substrate to each other when laminating the one electronic circuit substrate and the other electronic circuit substrate to each other.

4. The electric product according to claim 2,
wherein an electronic circuit substrate having the other connector terminal on the back surface has a gripping portion, which is gripped by a robot when assembling or disassembling the substrate laminate, on a portion of the front surface corresponding to the other connector terminal.

5. The electric product according to claim 2,
wherein the one connector terminal and the other connector terminal are a male terminal and a female terminal, or a plug and a receptacle.

6. The electric product according to claim 1, further comprising an attachment portion to which an electronic circuit substrate of a lowermost layer of the substrate laminate is attached,
wherein the attachment portion is provided with a positioning pin having a tip end which is directed to the electronic circuit substrate of the lowermost layer, and
wherein the electronic circuit substrate of the lowermost layer has a fitting hole in which the positioning pin of the attachment portion fits.

7. The electric product according to claim 6,
wherein the attachment portion is integrally formed with a container for storing the substrate laminate.
